(19) United States
(12) Patent Application Publication
(10) Pub. No.: US 2021/0066651 A1
(43) Pub. Date: Mar. 4, 2021

(54) ORGANIC EL DEVICE AND PRODUCTION METHOD THEREFOR

(71) Applicant: SAKAI DISPLAY PRODUCTS CORPORATION, Sakai-shi, Osaka (JP)

(72) Inventor: KATSUHIKO KISHIMOTO, Sakai-shi, Osaka (JP)

(21) Appl. No.: 16/765,679

(22) PCT Filed: Feb. 21, 2018
(86) PCT No.: PCT/JP2018/006130

§ 371 Date: Jul. 3, 2020

(51) Int. Cl. H01L 51/52; H01L 27/32; H01L 51/56

(52) U.S. Cl. CPC H01L 51/5253; H01L 27/3246; H01L 51/56; H01L 27/3276; H01L 27/326

(57) ABSTRACT

This organic EL device (100A) comprises a peripheral region (R2) and an active region (R1) containing a plurality of organic EL elements (3), and includes an element substrate (20) having a plurality of organic EL elements, and a thin film seal structure (10A) covering the plurality of organic EL elements. The thin film seal structure comprises a first inorganic barrier layer (12), an organic barrier layer (14) in contact with the upper surface of the first inorganic barrier layer, and a second inorganic barrier layer (16) in contact with the upper surface of the first inorganic barrier layer and the upper surface of the organic barrier layer. The peripheral region comprises a first protruding structure (22a) containing a section extending along at least one edge of the active region, and an extending section (12e) of the first inorganic barrier layer extending over the first protruding structure. The first protruding structure includes a first part and second part. The first part is closer to the top portion of the first protruding structure than the second part and, as observed from the normal direction to the base board, a cross section parallel to the substrate surface of the first part includes a part that does not overlap with the cross section parallel to the substrate surface of the second part.

### TECHNICAL FIELD

The present invention relates to an organic EL device and a method for producing the same.

### BACKGROUND ART

Organic EL (Electroluminescent) display devices start being put into practical use. One feature of an organic EL display device is flexibility thereof. An organic EL display device includes, in each of pixels, at least one organic EL element (Organic Light Emitting Diode: OLED) and at least one TFT (Thin Film Transistor) controlling an electric current to be supplied to each of the OLED. Hereinafter, an organic EL display device will be referred to as an “OLED display device”. Such an OLED display device including a switching element such as a TFT or the like for each of OLEDs is called an “active matrix OLED display device”. A substrate including the TFTs and the OLEDs will be referred to as an “element substrate”.

An OLED (especially, an organic light emitting layer and a cathode electrode material) is easily influenced by moisture to be deteriorated and to cause display unevenness. One technology developed to provide an encapsulation structure that protects the OLED against moisture while not spoiling the flexibility of the OLED display device is a thin film encapsulation (TFE) technology. According to the thin film encapsulation technology, an inorganic barrier layer and an organic barrier layer are stacked alternately to allow such thin films to provide a sufficiently high level of water vapor barrier property. From the point of view of the moisture-resistance reliability of the OLED display device, such a thin film encapsulation structure is typically required to have a WVTR (Water Vapor Transmission Rate) lower than, or equal to, 1×10⁻⁴ g/m²/day.

A thin film encapsulation structure used in OLED display devices commercially available currently includes an organic barrier layer (polymer barrier layer) having a thickness of about 5 μm to about 20 μm. Such a relatively thick organic barrier layer also has a role of flattening a surface of the element substrate.

Patent Documents Nos. 1 and 2 each describe a thin film encapsulation structure including an organic barrier layer formed of resin portions located locally. The thin film encapsulation structure described in Patent Document No. 1 or 2 does not include a thick organic barrier layer. Therefore, use of the thin film encapsulation structure described in Patent Document No. 1 or 2 is considered to improve the bendability of the OLED display device.

Patent Document No. 1 discloses a thin film encapsulation structure including a first inorganic material layer (first inorganic barrier layer), a first resin member and a second inorganic material layer (second inorganic barrier layer) provided on the element substrate in this order, with the first inorganic material layer being closest to the element substrate. In this thin film encapsulation structure, the first resin member is present locally, more specifically, around a protruding portion of the first inorganic material layer (first inorganic material layer covering the protruding portion). According to Patent Document No. 1, since the first resin member is present locally, more specifically, around the protruding portion, which may not be sufficiently covered with the first inorganic material layer, entrance of moisture or oxygen via the non-covered portion is suppressed. In addition, the first resin member acts as an underlying layer for the second inorganic material layer. Therefore, the second inorganic material layer is properly formed and properly covers a side surface of the first inorganic material layer with an expected thickness. The first resin member is formed as follows. An organic material heated and vaporized to be mist-like is supplied onto an element substrate maintained at a temperature lower than, or equal to, room temperature. The organic material is condensed and put into liquid drops on the substrate. The organic material in the liquid drops moves on the substrate by a capillary action or a surface tension to be present locally, more specifically, at a border between a side surface of the protruding portion of the first inorganic material layer and a surface of the substrate. Then, the organic material is cured to form the first resin member at the border. Patent Document No. 2 also discloses an OLED display device including a similar thin film encapsulation structure.

### CITATION LIST

### Patent Literature

Patent Document No. 1: WO2014/196137

Patent Document No. 2: Japanese Laid-Open Patent Publication No. 2016-39120

### SUMMARY OF INVENTION

### Technical Problem

The OLED display device is produced as follows, for example. First, an element substrate including a plurality of OLED display device portions each corresponding to an OLED display device is formed on a mother glass substrate. Next, a thin film encapsulation structure is formed on each of the OLED display device portions included in the element substrate. Then, the resultant assembly is divided into individual OLED display device portions, and a post-process is performed when necessary. As a result, the OLED display devices are produced. From the point of view of the moisture-resistance reliability, it is preferred that an active region of each of the resultant OLED display devices is fully enclosed by a portion where the first inorganic barrier layer and the second inorganic barrier layer are in direct contact with each other.

The present inventor produced experimental OLED display devices by the above-described method. Occasionally, a problem occurred that a sufficient moisture-resistance reliability was not provided.

According to the studies made by the present inventor, in a step of dividing the element substrate, when the inorganic material layer (the first inorganic barrier layer and/or the second inorganic barrier layer) included in the thin film encapsulation structure was present on a cutting line, the inorganic material layer was occasionally cracked from the position at which the element substrate was cut. Such a crack occasionally propagated along with time by thermal history or the like and reached the active region of the OLED display device.

The inorganic material layer included in the thin film encapsulation structure is formed by, for example, mask CVD so as to cover the active region of the OLED display device. In this step, the inorganic material layer is formed in a region larger than a region where the thin film encapsulation structure is to be formed, in consideration of the level of size precision of the mask CVD device and the alignment error between the mask and the element substrate. If the region where the inorganic material layer is formed is too large, the inorganic material layer is present on the cutting line of the element substrate and thus the above-described problem may occur. In addition, in order to improve the mass-productivity of the OLED display device, there is a tendency that the number of OLED display devices to be produced from one mother glass substrate is increased. As a result, the interval between adjacent OLED display device portions is decreased (to, for example, several millimeters), which is likely to cause the above-described problem.

The above-described problem is not limited to being caused to the OLED display device including a thin film encapsulation structure described in each of Patent Documents Nos. 1 and 2, and is common to OLED display devices including a thin film encapsulation structure that includes a relatively thick organic barrier layer (e.g., having a thickness exceeding 5 μm). Herein, the problem of the thin film encapsulation structure included in an OLED display device is described. However, the thin film encapsulation structure is not limited to being included in an OLED display device, and is also used in another organic EL device such as an organic EL illumination device or the like.

The present invention made to solve the above-described problem has an object of providing an organic EL device, including a thin film encapsulation structure, that has an improved moisture-resistance reliability, and a method for producing the same.

### Solution to Problem

An organic EL device according to an embodiment of the present invention is an organic EL device including an active region that includes a plurality of organic EL elements and also including a peripheral region located in a region other than the active region. The organic EL device includes an element substrate including a substrate and the plurality of organic EL elements supported by the substrate; and a thin film encapsulation structure covering the plurality of organic EL elements. The thin film encapsulation structure includes a first inorganic barrier layer, an organic barrier layer in contact with a top surface of the first inorganic barrier layer, and a second inorganic barrier layer in contact with the top surface of the first inorganic barrier layer and a top surface of the organic barrier layer. The peripheral region includes a first protruding structure supported by the substrate, the first protruding structure including a portion extending along at least one side of the active region, and also includes an extending portion, of the first inorganic barrier layer, extending onto the first protruding structure. The first protruding structure includes a first portion and a second portion, the first portion is closer to a top portion of the first protruding structure than the second portion, and as seen in a direction normal to the substrate, a first cross-section, parallel to a surface of the substrate, of the first portion includes a portion that does not overlap a second cross-section, parallel to the surface of the substrate, of the second portion.

In an embodiment, the first protruding structure has a height greater than a thickness of the first inorganic barrier layer. The thickness of the first inorganic barrier layer is, for example, the thickness thereof in the active region.

In an embodiment, the first protruding structure has a height that is at least three times as great as a thickness of the first inorganic barrier layer. The thickness of the first inorganic barrier layer is, for example, the thickness thereof in the active region.

In an embodiment, as seen in a cross-section perpendicular to a direction in which the first protruding structure extends, the first protruding structure includes a protruding portion protruding in a direction generally perpendicular to a height direction of the first protruding structure, and the protruding portion includes the first portion.

In an embodiment, as seen in a cross-section perpendicular to a direction in which the first protruding structure extends, the first protruding structure includes an inverted tapering portion in which a side surface of the first protruding structure has a tapering angle exceeding 90 degrees, and the inverted tapering portion includes the first portion and the second portion.

In an embodiment, the peripheral region includes an extending portion, of the second inorganic barrier layer, formed on the extending portion of the first inorganic barrier layer.

In an embodiment, the first protruding structure has a height that is at least three times as great as a sum of a thickness of the first inorganic barrier layer and a thickness of the second inorganic barrier layer. The thickness of the first inorganic barrier layer and the thickness of the second inorganic barrier layer are each the thickness thereof in the active region.

In an embodiment, as seen in a direction normal to the substrate, the second inorganic barrier layer does not overlap the first protruding structure.

In an embodiment, the element substrate further includes a bank layer defining each of a plurality of pixels each including any of the plurality of organic EL elements, and the first protruding structure has a height greater than, or equal to, a thickness of the bank layer.

In an embodiment, the first protruding structure includes a portion extending along three sides of the active region.

In an embodiment, the element substrate includes a plurality of gate bus lines each connected with any of the plurality of organic EL elements, and a plurality of source bus lines each connected with any of the plurality of organic EL elements. The peripheral region includes a plurality of terminals provided in a region in the vicinity of a certain side of the active region, and a plurality of lead wires connecting each of the plurality of terminals and either one of the plurality of gate bus lines or either one of the plurality of source bus lines to each other. The first protruding structure includes a portion extending along three sides of the active region other than the certain side.

In an embodiment, the organic barrier layer includes a plurality of solid portions distributed discretely. The second inorganic barrier layer is in contact with the top surface of the first inorganic barrier layer and top surfaces of the plurality of solid portions of the organic barrier layer.

In an embodiment, the organic barrier layer acts as a flattening layer having a thickness of 5 μm or greater.

In an embodiment, the peripheral region includes a second protruding structure between the active region and the first protruding structure, the second protruding structure extending along at least one side of the active region.

In an embodiment, the first protruding structure includes a plurality of sub structures.

A method for producing an organic EL device according to an embodiment of the present invention includes the steps of preparing an element substrate including a substrate and a plurality of active regions supported by the substrate, the plurality of active regions each including a plurality of organic EL elements; forming a thin film encapsulation structure in each of the plurality of active regions, the thin film encapsulation structure covering the plurality of organic EL elements; and dividing, after the step of forming the thin film encapsulation structure, the plurality of active regions into individual active regions. The step of preparing the element substrate includes step a1 of forming a first protruding structure in each of the plurality of active regions, the first protruding structure including a portion extending along at least one side of the corresponding active region. The first protruding structure includes a first portion and a second portion, the first portion is closer to a top portion of the first protruding structure than the second portion, and as seen in a direction normal to the substrate, a first cross-section, parallel to a surface of the substrate, of the first portion includes a portion that does not overlap a second cross-section, parallel to the surface of the substrate, of the second portion. The step of forming the thin film encapsulation structure includes step A of forming a first inorganic barrier layer on the first protruding structure such that the first inorganic barrier layer covers the first protruding structure, step B of, after the step A, forming an organic barrier layer on the first inorganic barrier layer, and step C of, after the step B, forming a second inorganic barrier layer on the first inorganic barrier layer and the organic barrier layer. The step of dividing the plurality of active regions includes the step of cutting the substrate and the first inorganic barrier layer such that individual cut portions each include either one of the plurality of active regions and the first protruding structure formed along the corresponding active region.

In an embodiment, the step of preparing the element substrate further includes step a2 of forming a bank layer defining each of a plurality of pixels each including either one of the plurality of organic EL elements. The step a1 and the step a2 include the step of patterning the same resin film.

In an embodiment, the first protruding structure includes a lower layer and an upper layer formed on the lower layer, and in a cross-section perpendicular to a direction in which the first protruding structure extends, a width of a bottom portion of the upper layer is greater than a width of a top portion of the lower layer. The step a1 includes step a11 of forming a lower film on the substrate, step a12 of forming an upper film on the lower film, step a13 of patterning the upper film to form the upper layer, and step a14 of patterning the lower film to form the lower layer.

In an embodiment, the lower film contains an acrylic resin, and the upper film contains silicon nitride.

In an embodiment, the step a13 includes the step of etching the upper film by use of hydrofluoric acid.

### Advantageous Effects of Invention

An embodiment of the present invention provides an organic EL device, including a thin film encapsulation structure, that has an improved moisture-resistance reliability, and a method for producing the same.

### BRIEF DESCRIPTION OF DRAWINGS

FIG. 1(a) is a schematic partial cross-sectional view of an active region of an OLED display device 100 according to an embodiment of the present invention, and FIG. 1(b) is a partial cross-sectional view of a TFE structure 10 formed on an OLED 3.

FIG. 2 is a plan view schematically showing a structure of an OLED display device 100A according to embodiment 1 of the present invention.

FIG. 3(a) and FIG. 3(b) are each a schematic cross-sectional view taken along line 3A-3A′ in FIG. 2, and respectively show OLED display devices 100A1 and 100A2.

FIG. 4 is a schematic view provided to describe a method for producing the OLED display device 100A, and schematically shows a mother panel 200A usable to form the OLED display device 100A.

FIG. 5(a) through FIG. 5(c) are each a schematic cross-sectional view showing a method for forming a protruding structure 22a2.

FIG. 6(a) through FIG. 6(c) are each a schematic cross-sectional view of the OLED display device 100A; FIG. 6(a) is a cross-sectional view taken along line 6A-6A′ in FIG. 2, FIG. 6(b) is a cross-sectional view taken along line 6B-6B′ in FIG. 2, and FIG. 6(c) is a cross-sectional view taken along line 6C-6C′ in FIG. 2.

FIG. 7(a) is an enlarged view of a portion including a particle P shown in FIG. 6(a), FIG. 7(b) is a schematic plan view showing the size relationship among the particle P, a first inorganic barrier layer (SiN layer) covering the particle P, and an organic barrier layer; and FIG. 7(c) is a schematic cross-sectional view of the first inorganic barrier layer covering the particle P.

FIG. 8 is a cross-sectional view schematically showing a structure of another OLED display device 100B according to embodiment 1 of the present invention.

FIG. 9 is a plan view schematically showing a structure of still another OLED display device 100C according to embodiment 1 of the present invention.

FIG. 10 is a schematic cross-sectional view of the OLED display device 100C taken along line 9A-9A′ in FIG. 9.

FIG. 11 is a plan view schematically showing a structure of still another OLED display device 100D according to embodiment 1 of the present invention.

FIG. 12 is a plan view schematically showing a structure of still another OLED display device 100E according to embodiment 1 of the present invention.

FIG. 13 is a cross-sectional view schematically showing a thin film encapsulation structure 10B included in an OLED display device according to embodiment 2 of the present invention.

### DESCRIPTION OF EMBODIMENTS

Hereinafter, an organic EL device and a method for producing the same according to embodiments of the present invention will be described with reference to the drawings. In the following, an OLED display device is described as an example of the organic EL device. Embodiments of the present invention are not limited to the embodiments described below as examples.

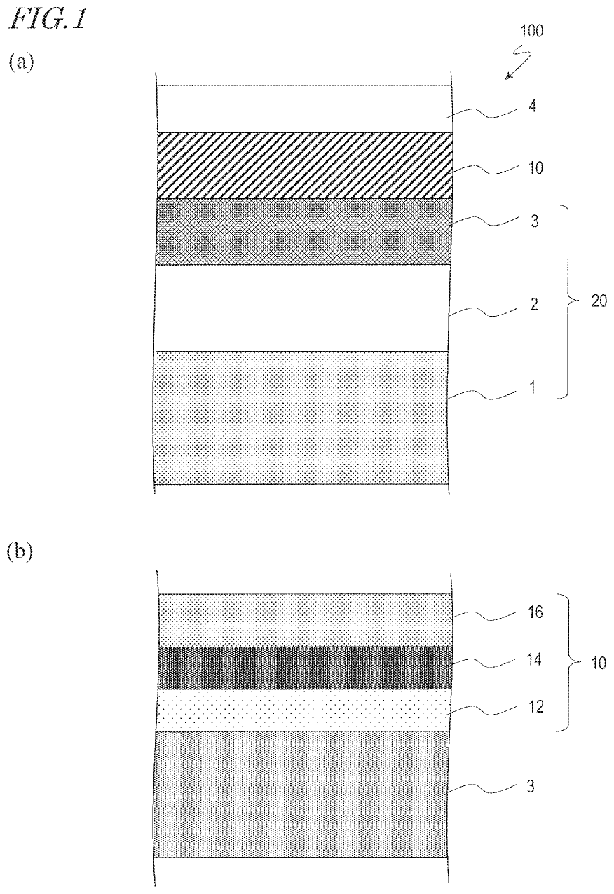

First, with reference to FIG. 1(a) and FIG. 1(b), a basic structure of an OLED display device 100 according to an embodiment of the present invention will be described. FIG. 1(a) is a schematic partial cross-sectional view of an active region of the OLED display device 100 according to an embodiment of the present invention. FIG. 1(b) is a partial cross-sectional view of a TFE structure 10 formed on an OLED 3. An OLED display device 100A according to embodiment 1 and an OLED display device according to embodiment 2 described below each have basically the same structure. Especially, components other than components regarding the TFE structure may be the same as those of the OLED display device 100.

The OLED display device 100 includes a plurality of pixels, and each of the pixels includes at least one organic EL element (OLED). Herein, a structure corresponding to one OLED will be described for the sake of simplicity.

As shown in FIG. 1(a), the OLED display device 100 includes a substrate (for example, a flexible substrate; hereinafter, may be referred to simply as a “substrate”) 1, a circuit (back plane) 2 formed on the substrate 1 and including a TFT, the OLED 3 formed on the circuit 2, and the TFE structure 10 formed on the OLED 3. The OLED 3 is, for example, of a top emission type. An uppermost portion of the OLED 3 is, for example, an upper electrode or a cap layer (refractive index adjusting layer). The substrate 1, the circuit 2 and the OLED 3 supported by the substrate 1 may be collectively referred to as an “element substrate 20”. The TFE structure 10 is formed on the element substrate 20. An optional polarizing plate 4 is located on the TFE structure 10. In the following, an example in which the substrate 1 is a flexible substrate will be described.

The substrate 1 is, for example, a polyimide film having a thickness of 15 μm. The circuit 2 including the TFT has a thickness of, for example, 4 μm. The OLED 3 has a thickness of, for example, 1 μm. The TFE structure 10 has a thickness of, for example, less than, or equal to, 1.5 μm.

FIG. 1(b) is a partial cross-sectional view of the TFE structure 10 formed on the OLED 3. The TFE structure 10 includes a first inorganic barrier layer (e.g., SiN layer) 12, an organic barrier layer (e.g., acrylic resin layer) 14 in contact with a top surface of the first inorganic barrier layer 12, and a second inorganic barrier layer (e.g., SiN layer) 16 in contact with the top surface of the first inorganic barrier layer 12 and a top surface of the organic barrier layer 14. The first inorganic barrier layer 12 is formed immediately on the OLED 3.

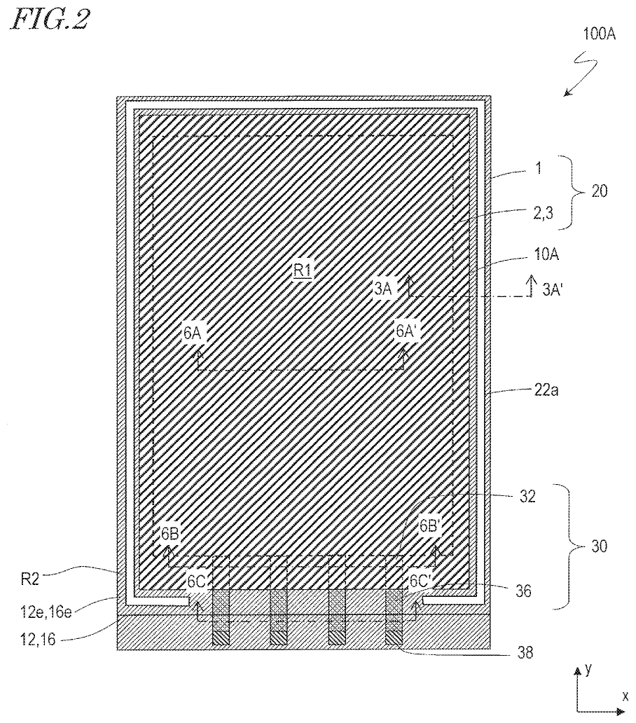

The TFE structure 10 is formed to protect an active region (see an active region R1 in FIG. 2) of the OLED display device 100. As described above, the TFE structure 10 includes, in at least the active region, the first inorganic barrier layer 12, the organic barrier layer 14 and the second inorganic barrier layer 16 provided in this order, with the first inorganic barrier layer 12 being closest to the OLED 3.

### Embodiment 1

With reference to FIG. 2 through FIG. 4, a structure of, and a method for producing, the OLED display device 100A according to embodiment 1 of the present invention will be described.

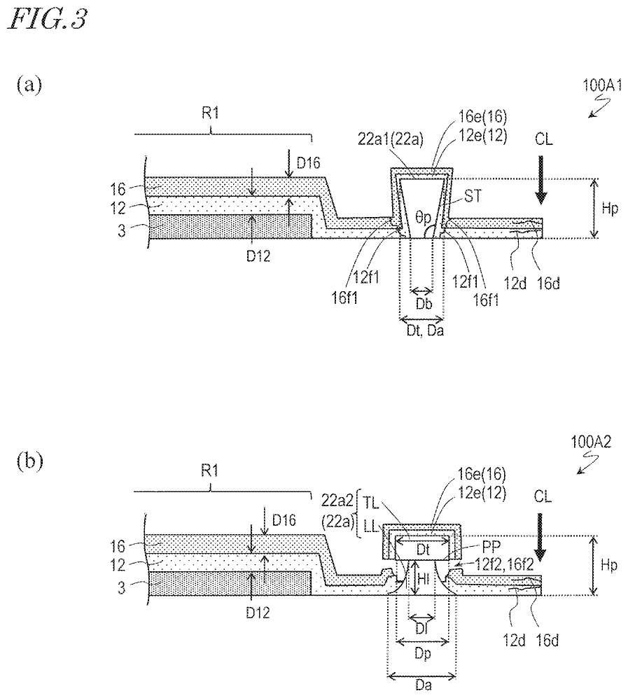

FIG. 2 is a plan view schematically showing the OLED display device 100A according to an embodiment of the present invention. FIG. 3(a) and FIG. 3(b) are each a cross-sectional view taken alone line 3A-3A′ in FIG. 2. FIG. 3(a) and FIG. 3(b) are respectively cross-sectional views schematically showing OLED display devices 100A1 and 100A2 respectively including a protruding structure 22a1 and a protruding structure 22a2 as examples of protruding structure 22a. The protruding structures 22a1 and 22a2 may collectively be referred to as the “protruding structure 22a”. The OLED display devices 100A1 and 100A2 may collectively be referred to as the “OLED display device 100A”.

As shown in FIG. 2, the OLED display device 100A includes the flexible substrate 1, the circuit (back plane) 2 formed on the flexible substrate 1, a plurality of the OLEDs 3 formed on the circuit 2, and a TFE structure 10A formed on the OLEDs 3. A layer including the plurality of OLEDs 3 may be referred to as an “OLED layer 3”. The circuit 2 and the OLED layer 3 may share a part of components. An optional polarizing plate (see reference numeral 4 in FIG. 1) may further be located on the TFE structure 10A. In addition, for example, a layer having a touch panel function may be located between the TFE structure 10A and the polarizing plate. Namely, the OLED display device 100 may be altered to a display device including an on-cell type touch panel.

The circuit 2 includes a plurality of TFTs (not shown), and a plurality of gate bus lines (not shown) and a plurality of source bus lines (not shown) each connected with any of the plurality of TFTs (not shown). The circuit 2 may be a known circuit that drives the plurality of OLEDs 3. The plurality of OLEDs 3 are each connected with either one of the plurality of TFTs included in the circuit 2. The OLEDs 3 may be known OLEDs.

The OLED display device 100A further includes a plurality of terminals 38 located in a peripheral region R2 outer to the active region R1 (region enclosed by the dashed line in FIG. 2), where the plurality of OLEDs 3 are located, and also includes a plurality of lead wires 30 connecting each of the plurality of terminals 38 and either one of the plurality of gate bus lines or either one of the plurality of source bus lines to each other. The TFE structure 10A is formed on the plurality of OLEDs 3 and on portions of the plurality of lead wires 30, the portions being closer to the active region R1. Namely, the TFE structure 10A covers the entirety of the active region R1 and is also selectively formed on the portions of the plurality of lead wires 30 that are closer to the active region R1. Neither portions of the plurality of lead wires 30 that are closer to the terminals 38, nor the terminals 38, are covered with the TFE structure 10A.

Hereinafter, an example in which the lead wires 30 and the terminals 38 are integrally formed in the same conductive layer will be described. Alternatively, the lead wires 30 and the terminals 38 may be formed in different conductive layers (encompassing stack structures).

As shown in FIG. 2 and FIG. 3, the peripheral region R2 of the OLED display device 100A includes a protruding structure 22a extending along at least one side of the active region R1 and an extending portion 12e, of the first inorganic barrier layer 12, extending onto the protruding structure 22a. The protruding structures 22a1 and 22a2 respectively shown in FIG. 3(a) and FIG. 3(b) each have the following structure. The protruding structure 22a includes a first portion and a second portion. The first portion is closer to a top portion of the protruding structure 22a than the second portion. As seen in a direction normal to the substrate 1, a first cross-section, parallel to a surface of the substrate, of the first portion includes a portion that does not overlap a second cross-section, parallel to the surface of the substrate, of the second portion.

This will be described specifically. As shown in, for example, FIG. 3(a), as seen in a cross-section perpendicular to a direction in which the protruding structure 22a1 extends (e.g., the cross-section shown in FIG. 3(a)), the protruding structure 22a1 includes an inverted tapering portion ST, in which a side surface of the protruding structure 22a1 has a tapering angle θp exceeding 90 degrees. The inverted tapering portion ST includes the first portion and/or the second portion.

Alternatively, as shown in FIG. 3(b), as seen in a cross-section perpendicular to a direction in which the protruding structure 22a2 extends (e.g., the cross-section shown in FIG. 3(b)), the protruding structure 22a2 includes a protruding portion PP protruding in a direction generally perpendicular to a height direction of the protruding structure 22a2. The protruding portion PP includes the first portion.

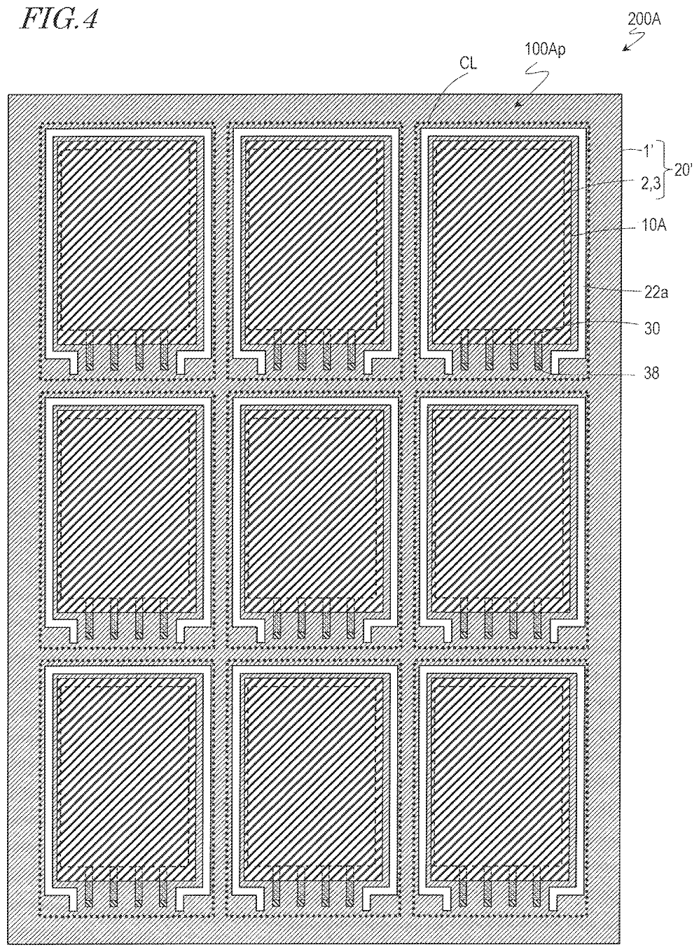

With reference to FIG. 4, a method for producing the OLED display device 100A will be described. FIG. 4 schematically shows a mother panel 200A usable to form the OLED display device 100A.

As shown in FIG. 4, the mother panel 200A includes an element substrate 20′ and the thin film encapsulation structures 10A formed on the element substrate 20′. The element substrate 20′ is formed on a mother glass substrate (not shown; for example, G4.5 (730 mm×920 mm)). The element substrate 20′ includes a plurality of OLED display device portions 100Ap, each of which is to be the OLED display device 100A. The element substrate 20′ includes a substrate 1′ and also includes the circuit 2 and a plurality of organic EL elements 3 supported by the substrate 1′. The circuit 2 and the plurality of organic EL elements 3 are provided in each of the OLED display device portions 100Ap, and are supported by the common substrate 1′. The thin film encapsulation structures 10A are each formed so as to protect the active region R1 of the corresponding OLED display device portion 100Ap. The mother panel 200A is divided into individual OLED display device portions 100Ap along a cutting line CL, and then a post-process is performed when necessary. As a result, the OLED display devices 100A are produced. The substrate 1′ is divided and as a result, becomes the substrate 1 of each of the OLED display devices 100A. Thus, the element substrate 20 included in each OLED display device 100A is provided.

Namely, the method for producing the OLED display device 100A according to an embodiment of the present invention includes the following steps.

Step (1): step of preparing the element substrate 20′ including the substrate 1′ and a plurality of the active regions R1 supported by the substrate 1′, the plurality of active regions R1 each including a plurality of the organic EL elements 3,

Step (2): step of forming the thin film encapsulation structure 10A in each of the plurality of active regions R1, the thin film encapsulation structure 10A covering the plurality of organic EL elements 3, and

Step (3): step of, after step (2), dividing the plurality of active regions R1 into individual active regions R1.

Step (1) includes the step of forming the protruding structure 22a in each of the plurality of active regions R1, the protruding structure 22a including a portion extending along at least one side of the corresponding active region R1.

Step (2) includes the following steps.

Step A: step of forming the first inorganic barrier layer 12 on the protruding structure 22a such that the first inorganic barrier layer 12 covers the protruding structure 22a.

Step B: step of, after the step A, forming the organic barrier layer 14 on the first inorganic barrier layer 12.

Step C: step of, after the step B, forming the second inorganic barrier layer 16 on the first inorganic barrier layer 12 and the organic barrier layer 14.

Step (3) includes the step of cutting the substrate 1′ and the first inorganic barrier layer 12 such that individual cut portions each include either one of the plurality of active regions R1 and the protruding structure 22a formed in the corresponding active region R1.

In mass-production, a plurality of the element substrates 20 are formed on the mother glass substrate. Step (3) may further include the step of cutting the mother glass substrate or the step of partially shaving the mother glass substrate (for example, from the surface to a level of a certain depth). The substrate (e.g., flexible substrate) 1′ is cut by, for example, laser beam irradiation. The laser beam may have a wavelength in either an infrared region, a visible light region or an ultraviolet region. From the point of view of suppressing the influence on the mother glass substrate by the cutting, it is desired to use a laser beam having a wavelength included in a green to ultraviolet region.

The method for producing the OLED display device 100A according to an embodiment of the present invention further includes, for example, the step of delaminating the element substrate 20 from the mother glass substrate after the step of cutting the substrate 1′ and the first inorganic barrier layer 12.

Before the element substrate 20 is delaminated from the mother glass substrate, for example, laser lift-off is carried out such that the substrate 1′ (or the substrate 1) is irradiated with ultraviolet laser light transmitted through the mother glass substrate. A part of the substrate 1′ (or the substrate 1) at an interface with the mother glass substrate needs to absorb such ultraviolet laser light and decompose (disappear). After the laser lift-off, the element substrate 20 is delaminated from the mother glass substrate. The laser lift-off may be performed before the step of cutting the substrate 1′ and the first inorganic barrier layer 12, or may be performed after the step of cutting the substrate 1′ and the first inorganic barrier layer 12. The term “laser lift-off” here refers to weakening the joining (adhesion) between the mother glass substrate and the element substrate 20 by laser irradiation, and does not encompass physically delaminating.

The first inorganic barrier layer 12 and the second inorganic barrier layer 16 are formed by, for example, plasma CVD using a mask, selectively only in a predetermined region so as to cover the active region R1 of each of the OLED display device portions 100Ap. It is preferred that the active region R1 of each of the OLED display device portions 100Ap is fully enclosed by a portion where the first inorganic barrier layer 12 and the second inorganic barrier layer 16 are in direct contact with each other (hereinafter, such a portion will be referred to as an “inorganic barrier layer joint portion”). As long as the active region R1 is fully enclosed by the inorganic barrier layer joint portion, the first inorganic barrier layer 12 and the second inorganic barrier layer 16 may have any shape. For example, the shape of the second inorganic barrier layer 16 may be the same as the shape of the first inorganic barrier layer 12 (outer perimeters thereof may match each other). Alternatively, the second inorganic barrier layer 16 may be formed so as to cover the entirety of the first inorganic barrier layer 12. Still alternatively, the first inorganic barrier layer 12 may be formed so as to cover the entirety of the second inorganic barrier layer 16. An external shape of the TFE structure 10A is defined by, for example, the inorganic barrier layer joint portion formed by the first inorganic barrier layer 12 and the second inorganic barrier layer 16.

In the plan views of FIG. 2 and FIG. 4, only the region where each of the TFE structure 10A is to be formed is shown as the TFE structure 10A. The region where the TFE structure 10A is to be formed is a region that covers at least the active region R1, includes the inorganic barrier layer joint portion, and is inner to the cutting line CL. A reason for this is that if the first inorganic barrier layer 12 and/or the second inorganic barrier layer 16 is present on the cutting line CL, the number of layers to be cut in the step of cutting the element substrate 20′ is increased, which may increase the production cost. The region where the TFE structure 10A is to be formed shown in FIG. 2 and FIG. 4 corresponds to, for example, the shape of a CVD mask used to form the first inorganic barrier layer 12 and/or the second inorganic barrier layer 16.

However, in actuality, as shown in the cross-sectional view of FIG. 3, there is a case where the region where the first inorganic barrier layer 12 and/or the second inorganic barrier layer 16 is formed is larger than the region where the TFE structure 10A is to be formed, due to, for example, the level of size precision of the mask CVD device. In addition, there is a case where the first inorganic barrier layer 12 is formed in a region larger than the region where the thin film encapsulation structure 10A is to be formed, in consideration of the alignment error between the mask for the first inorganic barrier layer 12 and the element substrate 20′. From the point of view of improving the mass-productivity of the OLED display device, it is preferred that the distance between adjacent OLED display device portions 100Ap formed on the mother glass substrate is small (e.g., several millimeters (e.g., 3 mm)). In such cases, the first inorganic barrier layer 12 and/or the second inorganic barrier layer 16 may be present on the cutting line CL. In this specification, a portion of the first inorganic barrier layer 12 that is formed in a region other than the region where the TFE structure 10A is to be formed may be referred to as the “extending portion 12e”. The same is applicable to the second inorganic barrier layer 16. A portion of the second inorganic barrier layer 16 that is formed in a region other than the region where the TFE structure 10A is to be formed may be referred to as an “extending portion 16e”.

As shown in FIG. 3(a) and FIG. 3(b), in the resultant OLED display device 100A, a crack 12d may be generated in the first inorganic barrier layer 12 from the cut position (cutting line CL). The crack 12d propagates along with time due to thermal history or the like. If the protruding structure 22a is not present, the crack 12d may reach the active region R1 via the first inorganic barrier layer 12. However, the OLED display device 100A includes the protruding structure 22a formed below the first inorganic barrier layer 12, and therefore, suppresses the crack 12d from reaching the active region R1. The moisture-resistance reliability of the OLED display device 100A is improved.

As shown in FIG. 3(a), a defect 12f1 is likely to be formed in the first inorganic barrier layer 12 (extending portion 12e) at the border between a flat surface on which the protruding structure 22a1 is formed and a side surface of the protruding structure 22a1. The defect 12f1 is especially likely to be formed at the inverted tapering portion PT in the side surface of the protruding structure 22a1. A reason for this is that a portion having a low density (low film density) is formed in an area where the SiN film growing from the flat surface and the SiN film growing from the side surface impinge on each other. In an extreme case, such a defect may become a crack. The defect 12f1 is formed linearly along the direction in which the protruding structure 22a1 extends. If the crack 12d generated in the first inorganic barrier layer 12 in the dividing step propagates toward the active region R1, a tip of the crack 12d reaches the linear defect 12f1 formed along the direction in which the protruding structure 22a1 extends. When this occurs, the stress at the tip of the crack 12d is released, and the crack 12d is prevented from propagating beyond the linear defect 12f1.

In the example shown in FIG. 3(b), a defect 12f2 is likely to be formed in the first inorganic barrier layer 12 (extending portion 12e) at the protruding portion PP of the protruding structure 22a2. The defect 12f2 may be, for example, a gap in the first inorganic barrier layer 12. The defect 12f2 is also formed linearly along the direction in which the protruding structure 22a2 extends, and therefore, prevents the crack 12d from propagating beyond the linear defect 12f2.

In the example shown here, the second inorganic barrier layer 16 is also formed on the cutting line CL. Therefore, as shown in FIG. 3(a) and FIG. 3(b), a crack 16d may also be formed in the second inorganic barrier layer 16 from the cut position (cutting line CL) in the resultant OLED display device 100A. The second inorganic barrier layer 16 includes the extending portion 16e formed on the extending portion 12e of the first inorganic barrier layer 12. The second inorganic barrier layer 16 reflects stepped portions formed by the defects 12f1 and 12f2 in the first inorganic barrier layer 12, which is an underlying layer for the second inorganic barrier layer 16. Therefore, the extending portion 16e of the second inorganic barrier layer 16 includes defects 16f1 and 16f2. As a result, the second inorganic barrier layer 16 suppresses the crack 16d from reaching the active region R1.

Herein, an example in which the first inorganic barrier layer 12 and the second inorganic barrier layer 16 are selectively formed in only a predetermined region so as to cover the active region R1 is described. This embodiment is not limited to this. The first inorganic barrier layer 12 and/or the second inorganic barrier layer 16 may be formed on the entirety of a surface of the element substrate 20′ formed on the mother glass substrate. In this case also, the provision of the protruding structure 22a improves the moisture-resistance reliability of the resultant OLED display devices as described above.

Even if a defect (linear defect) caused by the protruding structure 22a is formed at a position closer to the active region R1 than the protruding structure 22a of the first inorganic barrier layer 12 and/or the second inorganic barrier layer 16, the moisture-resistance reliability of the OLED display device is not influenced as long as each active region R1 is completely enclosed by the inorganic barrier layer joint portion.

The protruding structure 22a is not limited to being shaped as shown in any of the figures. As described above, the protruding structure 22a merely needs to be shaped as follows. The protruding structure 22a includes the first portion and the second portion. The first portion is closer to the top portion of the protruding structure 22a than the second portion. As seen in the direction normal to the substrate 1, the first cross-section, parallel to the surface of the substrate, of the first portion includes a portion that does not overlap the second cross-section, parallel to the surface of the substrate, of the second portion. The protruding structure 22a having such a shape forms a defect in the first inorganic barrier layer 12 (extending portion 12e), which prevents the crack 12d from propagating beyond the linear defect.

For example, FIG. 3(a) shows the cross-section, of the protruding structure 22a1, perpendicular to the direction in which the protruding structure 22a1 extends. The protruding structure 22a1 includes the inverted tapering portion at both of the side surfaces thereof in the cross-section shown in FIG. 3(a). Alternatively, the protruding structure may have the inverted tapering portion only at a part of the side surfaces. Namely, the tapering angle of only a part of the side surface may exceed 90 degrees.

The protruding structure 22a2 shown in FIG. 3(b) includes a lower layer LL and an upper layer TL formed on the lower layer LL. In the cross-section perpendicular to the direction in which the protruding structure 22a2 extends, width Dp of a bottom portion of the upper layer TL is greater than width Dl of a top portion of the lower layer LL. Such an arrangement forms the protruding portion PP. Namely, the protruding portion PP includes a portion, of the bottom portion of the upper layer TL, that protrudes from the top portion of the lower layer LL. As seen in the direction normal to the substrate 1, the cross-section of the bottom portion of the upper layer TL of the protruding structure 22a2 includes a portion that does not overlap the cross-section of the top portion of the lower layer LL. Here, the bottom portion of the upper layer TL is closer to the top portion of the protruding structure 22a2 than the top portion of the lower layer LL.

In the cross-section perpendicular to the direction in which the protruding structure 22a2 extends, the width Dp of the bottom portion of the upper layer TL is preferably at least 2.5 times as great as height Hi of the lower layer LL, and more preferably at least three times as great as the height Hl. In the cross-section perpendicular to the direction in which the protruding structure 22a2 extends, the lower layer LL is, for example, generally trapezoidal, whereas the upper layer TL is, for example, generally rectangular. Here, for example, the width Dp of the bottom portion of the upper layer TL is generally equal to width Dt of a top portion of the upper layer TL (namely, the width of the top portion of the protruding structure 22a2). In the example shown in FIG. 3(b), in the cross-section shown in FIG. 3(b), the protruding structure 22a2 includes the protruding portion PP at both of left and right sides. The protruding structure is not limited to having such a structure. For example, the protruding structure may include the protruding portion only at one of the sides. The protruding portion merely needs to cause a defect in the first inorganic barrier layer 12 (extending portion 12e) formed on the protruding structure. The direction in which the protruding portion protrudes is not limited to the direction perpendicular to the height direction of the protruding structure.

Height Hp of the protruding structure 22a is, for example, greater than thickness D12 of the first inorganic barrier layer 12. In the case where the height Hp of the protruding structure 22a is at least three times as great as the thickness D12 of the first inorganic barrier layer 12, a defect is more likely formed in the first inorganic barrier layer 12 (extending portion 12e), which is preferred. In the case where the second inorganic barrier layer 16 includes the extending portion 16e formed on the extending portion 12e of the first inorganic barrier layer 12, it is more preferred that the height Hp of the protruding structure 22a is at least three times as great as a sum of the thickness D12 of the first inorganic barrier layer 12 and thickness D16 of the second inorganic barrier layer 16. The “thickness D12 of the first inorganic barrier layer 12” refers to the thickness of a portion of the first inorganic barrier layer 12 that is formed in the active region R1. The “thickness D16 of the second inorganic barrier layer 16” refers to the thickness of a portion of the second inorganic barrier layer 16 that is formed in the active region R1. It should be noted that the height Hp of the protruding structure 22a may be less than, or equal to, the thickness D12 of the first inorganic barrier layer 12. Even in this case, as long as the cross-section of the protruding structure 22a is shaped as described above, a defect may be formed in the first inorganic barrier layer 12 (extending portion 12e).

The extending portion 12e of the first inorganic barrier layer 12 may have a thickness that is, for example, generally equal to the thickness D12 of the first inorganic barrier layer 12 in the active region R1. Similarly, the extending portion 16e of the second inorganic barrier layer 16 may have a thickness that is, for example, generally equal to the thickness D16 of the second inorganic barrier layer 16 in the active region R1. However, this embodiment is not limited to this. For example, the thickness of the extending portion 12e of the first inorganic barrier layer 12 may be less than the thickness D12 of the first inorganic barrier layer 12 in the active region R1. The thickness of the extending portion 16e of the second inorganic barrier layer 16 may be less than the thickness D16 of the second inorganic barrier layer 16 in the active region R1. In the case where the thickness of the extending portion 12e of the first inorganic barrier layer 12 is thus small, a defect may be formed in the first inorganic barrier layer 12 even at a top surface of the protruding structure 22a.

Width Da of the protruding structure 22a, more specifically, the width Da of the cross-section perpendicular to the direction in which the protruding structure 22a extends, is, for example, 10 μm or less. In this case, the provision of the protruding structure 22a does not significantly influence the reduction in the width of the frame portion of the OLED display device 100A. The “width Da of the protruding structure 22a” is the width in the direction perpendicular to the height direction of the protruding structure 22a.

The protruding structure 22a1 including the inverted tapering portion at a side surface thereof is formed by, for example, a photolithography process by use of a negative photosensitive resin. A resin film formed of a negative photosensitive resin is exposed under such conditions that cause underexposure, and then is overexposed. As a result, the protruding structure 22a1 including the inverted tapering side surface is formed. A resin composition containing a negative photosensitive resin and an ultraviolet absorber added thereto may be used to adjust the exposure conditions so as to cause underexposure. The formation of the inverted tapering side surface is not limited to such an example. A known photolithography process may be used to form the inverted tapering side surface.

The protruding structure 22a1 may be formed in, for example, the same step as the step of forming a bank layer (may also be referred to as a “PDL” (pixel defining layer); not shown) defining each of the plurality of pixels. Namely, the protruding structure 22a1 and the bank layer may be formed by pattering the same resin film. The step of forming the protruding structure 22a1 and the step of forming the bank layer may include the step of patterning the same resin film. It is preferred that the bank layer has a tapering angle of 90 degrees or smaller. Therefore, it is preferred that the patterning of the protruding structure 22a1 and the patterning of the bank layer (patterning includes exposure and development) are performed under different conditions from each other. In this case, the patterning of the protruding structure 22a1 and the patterning of the bank layer may be performed in different steps by use of different photomasks from each other. Alternatively, for example, a multi-gray scale mask (a half-tone mask or a gray tone mask) may be used to pattern the protruding structure 22a1 and the bank layer. In this case, one same photomask and/or one same etchant may be used to pattern the protruding structure 22a1 and the bank layer. The “multi-gray scale mask” is a photomask including regions having at least three different levels of transmittance (minimum value, maximum value, and an intermediate value between the minimum value and the maximum value). For example, after a resin film is formed of a negative photosensitive resin, the resin film may be exposed by use of a photomask in which the region corresponding to the protruding structure 22a1 and the region corresponding to the bank layer have different exposure amounts. The photomask may be used such that the exposure amount of the region corresponding to the protruding structure 22a1 is smaller than the exposure amount of the region corresponding to the bank layer. In addition, in the region corresponding to the bank layer, a region corresponding to a portion that is to have a side surface having a small tapering angle may have a smaller exposure amount than that of the remaining region. Such a photomask may be considered to include a multi-gray scale mask portion corresponding to the bank layer and a binary mask portion corresponding to the protruding structure 22a1.

The bank layer is formed, for example, between a lower electrode acting as an anode electrode of the OLED 3 and an organic layer (organic light emitting layer) formed on the lower electrode. The bank layer has a thickness of several micrometers (e.g., 1 μm to 2 μm). Therefore, the protruding structure 22a1 may have the same height as that of the bank layer. A photolithography process using a multi-gray scale mask as described above may be used to cause the protruding structure 22a1 to have a height different from the height of the bank layer. Alternatively, the protruding structure 22a1 may be formed in any of the steps of forming the circuit (back plane) 2. For example, the protruding structure 22a1 may be formed of the same resin film as that of a flattening layer acting as an underlying layer for the lower electrode of the OLED 3. Needless to say, the protruding structure 22a1 may be formed in a step different from the steps of forming the circuit (back plane) 2.

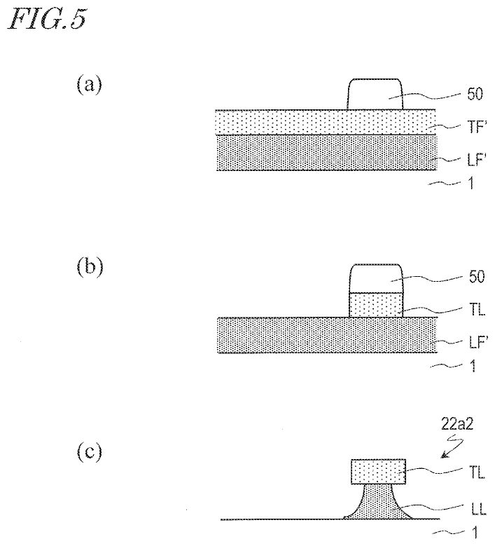

With reference to FIG. 5(a) through FIG. 5(c), an example of method for forming the protruding structure 22a2 including the protruding portion PP will be described.

First, as shown in FIG. 5(a), a lower resin film LF′ is provided on the substrate 1, and an upper film TF′ (e.g., SiN film) is formed on the lower resin film LF′ by, for example, plasma CVD. Then, a resist layer 50 is formed of a photoresist (e.g., negative photoresist) on the upper film TF′. In this example, the lower resin film LF′ is formed after the bank layer is formed. The lower resin film LF′ is formed of, for example, a negative photosensitive resin (e.g., acrylic resin). The lower resin film LF′ may be thermally treated (pre-baked) before the upper film TF′ is formed. It is preferred that the upper film TF′ is deposited at a low temperature (e.g., 80° C. or lower) and at normal pressure.

Next, as shown in FIG. 5(b), the upper film TF′ is patterned using the resist layer 50 as an etching mask to form the upper layer TL. The upper film TF′ is patterned using, for example, hydrofluoric acid as the etchant. It is preferred that the lower resin film LF′ is resistant to the etchant for the upper film TF′. Namely, it is preferred that the lower resin film LF′ has an etching rate lower than that of the upper film TF′. For example, an acrylic resin is resistant to hydrofluoric acid.

Next, the resist layer 50 is removed, and then the lower resin film LF′ is patterned using the upper layer TL as an etching mask. As a result, as shown in FIG. 5(c), the lower layer LL is formed. The lower resin film LF′ is patterned with wet etching. For the patterning, the lower resin film LF′ is over-etched such that a portion thereof below the upper layer TL, which is the etching mask, is etched away (such that undercut is performed). In this manner, the protruding structure 22a2 including the lower layer LL and the upper layer TL is formed. The width Di of the top portion of the lower layer LL is less than the width Dp of the bottom portion of the upper layer TL. The width Dp of the bottom portion of the upper layer TL is preferably at least 2.5 times as great as the height Hi of the lower layer LL, and more preferably at least three times as great as the height Hl. The resist layer 50 may be removed after the lower layer LL is formed.

The protruding structure 22a2 may also be formed by the following method. The lower layer LL of the protruding structure 22a2 and the bank layer may be formed by patterning the same resin film (i.e., lower resin film LF′). In this case, after the upper layer TL is formed and the resist layer 50 is removed, another resist layer including openings corresponding to the lower layer LL and the bank layer may be formed as an etching mask for the lower resin film LF′.

Alternatively, two types of photosensitive resins having different levels of photosensitivity may be used to form the protruding structure 22a2. In this case, the upper layer TL and the lower layer LL are both a resin layer. The top resin film TF′ is formed of a photosensitive film having a higher level of photosensitivity than that of a photosensitive film used to form the lower resin film LF′. The photosensitivity of a photosensitive resin may be adjusted by, for example, changing the amount of photoinitiator contained in the resin. After the lower resin film LF′ is provided on the substrate 1 but before the top resin film TF′ is provided thereon, the lower resin film LF′ may be thermally treated (pre-baked (e.g., at 130° C. for 2 minutes)). After the top resin film TF′ is provided, the lower resin film LF′ and the top resin film TF′ are patterned by a photolithography process. The lower resin film LF′ and the top resin film TF′ are patterned to have different shapes because of the different levels of sensitivity thereof.

In the case where the organic light emitting layer of the OLED 3 is formed by mask deposition, the protruding structure 22a may also act as a spacer used to form a desired gap between the deposition mask and the surface of the element substrate. Alternatively, the protruding structure 22a may also act as a spacer used to support a touch sensor layer or a substrate (protective layer) located on the TFE structure 10A. In the case where the protruding structure 22a acts as a spacer, it is preferred that the height of the protruding structure 22a is equal to, or greater than, the thickness of the bank layer. In the case where the protruding structure 22a acts as a spacer, the depth Dt of the top portion of the protruding structure 22a in the cross-section perpendicular to the direction in which the protruding structure 22a extends is preferably 5 μm or greater, and is more preferably 10 μm or greater.

As shown in FIG. 2, the protruding structure 22a includes a portion extending along three sides, among the four sides of the active region R1, other than the side along which the plurality of terminals 38 and the plurality of lead wires 30 are provided (other than the bottom side in FIG. 2 among the sides extending in an x-axis direction). For, for example, a middle- or small-sized OLED display device, it is required to decrease the width of three peripheral regions, among four, i.e., top, bottom, left and right, peripheral regions outer to the active regions R1, other than one peripheral region in which the terminals of the lines are drawn. Therefore, the inorganic barrier layer is likely to be formed on the cutting line CL in the three peripheral regions as described above. Nonetheless, provision of the protruding structure 22a in these three peripheral regions improves the moisture-resistance reliability. By contrast, the width of the peripheral region in which the terminals of the lines are drawn is not required to be decreased significantly. Therefore, it is easy to form the inorganic barrier layer such that the inorganic barrier layer does not overlap the cutting line CL. This allows the protruding structure 22a to be omitted. As shown in FIG. 2, the protruding structure 22a may be provided along the four sides of the active region R1 except for a portion where the plurality of terminals 38 are provided. It is preferred that the protruding structure 22a is provided so as to interrupt a line (e.g., straight line) connecting the cutting line CL and an outer perimeter of the active region R1 to each other, except for the portion where the plurality of terminals 38 are provided.

The protruding structure is not limited to having a planar shape (shape as seen in the direction normal to the substrate) shown here as an example. The protruding structure may extend along two sides, among the four sides of the active region R1, other than two sides along which the plurality of terminals are provided. For example, a large-sized OLED display device may have a structure in which terminals of the lines are drawn in two peripheral regions facing each other (top and bottom peripheral regions or left and right peripheral regions) among the four, i.e., top, bottom, left and right, peripheral regions outer to the active region R1. The protruding structure does not need to be formed as a single structure, and may include a plurality of sub structures. It is sufficient that the plurality of sub structures, as a whole, interrupt between the cutting line CL and the outer perimeter of the active region R1. Examples of the positional arrangement and the planar shape of the protruding structure will be described below.

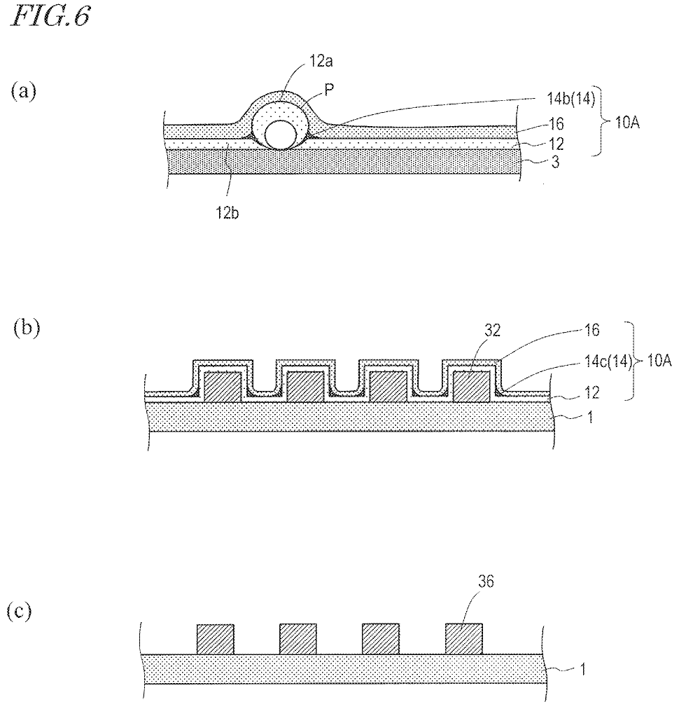

Now, with reference to FIG. 6(a) through FIG. 6(c), the TFE structure 10A of the OLED display device 100A will be described. FIG. 6(a) is a cross-sectional view taken along line 6A-6A′ in FIG. 2, FIG. 6(b) is a cross-sectional view taken along line 6B-6B′ in FIG. 2, and FIG. 6(c) is a cross-sectional view taken along line 6C-6C′ in FIG. 2.

As shown in FIG. 6(a) and FIG. 6(b), the TFE structure 10A includes the first inorganic barrier layer 12 formed on the OLED 3, the organic barrier layer 14, and the second inorganic barrier layer 16 in contact with the first inorganic barrier layer 12 and the organic barrier layer 14. In this example, the organic barrier layer 14 includes a plurality of solid portions in contact with the top surface of the first inorganic barrier layer 12 and distributed discretely. The second inorganic barrier layer 16 is in contact with the top surface of the first inorganic barrier layer 12 and top surfaces of the plurality of solid portions of the organic barrier layer 14. The organic barrier layer 14 is not present as a film covering the entirety of the active region, but includes an opening. A portion of the organic barrier layer 14 excluding the opening, more specifically, a portion where the organic film is actually present, will be referred to as a “solid portion”. The opening (may also be referred to as a “non-solid portion”) does not need to be enclosed by the solid portion, and may include a cut-out portion or the like. In the opening, the first inorganic barrier layer 12 and the second inorganic barrier layer 16 are in direct contact with each other. The opening of the organic barrier layer 14 includes at least an opening formed to enclose the active region R1, and the active region R1 is completely enclosed by the portion in which the first inorganic barrier layer 12 and the second inorganic barrier layer 16 are in direct contact with each other (“inorganic barrier layer joint portion”).

The first inorganic barrier layer 12 and the second inorganic barrier layer 16 are each, for example, an SiN layer having a thickness of, for example, 400 nm. The organic barrier layer 14 is, for example, an acrylic resin layer having a thickness less than 100 nm. The first inorganic barrier layer 12 and the second inorganic barrier layer 16 each have a thickness of 200 nm or greater and 1000 nm or less independently. The thickness of the organic barrier layer 14 is 50 nm or greater and less than 200 nm. The thickness of the TFE structure 10A is preferably 400 nm or greater and less than 2 μm, and is more preferably 400 nm or greater and less than 1.5 μm.

As described above, the first inorganic barrier layer 12 and the second inorganic barrier layer 16 are each selectively formed only in a predetermined region by plasma CVD by use of a mask so as to cover the active region R1. In general, a surface of a layer formed by a thin film deposition method (e.g., CVD, sputtering, vacuum vapor deposition) reflects a stepped portion in an underlying layer. The organic barrier layer (solid portion) 14 is formed only around a protruding portion at the surface of the first inorganic barrier layer 12. The first inorganic barrier layer 12 is formed on the protruding structure 22a so as to cover the protruding structure 22a.

The organic barrier layer 14 may be formed by the method described in, for example, Patent Document No. 1 or 2. For example, a vapor-like or mist-like organic material (e.g., acrylic monomer) is supplied, in the chamber, onto an element substrate maintained at a temperature lower than, or equal to, room temperature, and is condensed on the element substrate. The organic material put into a liquid state is located locally, more specifically, at the border between a side surface of the protruding portion of the first inorganic barrier layer 12 and a flat portion of the first inorganic barrier layer 12 by a capillary action or a surface tension of the organic material. Then, the organic material is irradiated with, for example, ultraviolet rays to form the solid portion of the organic barrier layer (e.g., acrylic resin layer) 14 at the border around the protruding portion. The organic barrier layer 14 formed by this method includes substantially no solid portion on the flat portion. Regarding the method for forming the organic barrier layer, the disclosures of Patent Documents Nos. 1 and 2 are incorporated herein by reference.

In the case where, as in the example shown in FIG. 3, the second inorganic barrier layer 16 is formed on the protruding structure 22a, it is preferred that the organic barrier layer 14 is not formed on the first inorganic barrier layer 12 (extending portion 12e) formed on the protruding structure 22a. If the organic barrier layer 14 is formed so as to fill the defect 12f1 or 12f2 of the first inorganic barrier layer 12, the stepped portion caused by the defect 12f1 or 12f2 of the first inorganic barrier layer 12 is not reflected in the second inorganic barrier layer 16. In this case, the defect 16f1 or 16f2 is not formed in the second inorganic barrier layer 16, and thus the crack 16d generated in the second inorganic barrier layer 16 may not be suppressed from reaching the active region R1. Therefore, it is preferred that, for example, any one of the following methods is combined with the method described in Patent Document No. 1 or 2 to prevent the organic barrier layer 14 from being formed on the first inorganic barrier layer 12 (extending portion 12e) formed on the top surface and the side surface of the protruding structure 22a. Any two or more of the methods described below may be combined.

Even if the crack generated in the second inorganic barrier layer 16 reaches the active region R1, the possibility that the moisture-resistance reliability of the OLED display device is declined is low as long as the active region R1 is sufficiently covered with the first inorganic barrier layer 12. The influence exerted on the moisture-resistance reliability by the crack generated in the second inorganic barrier layer 16 reaching the active region R1 is smaller than the influence exerted on the moisture-resistance reliability by the crack generated in the first inorganic barrier layer 12 reaching the active region R1. Therefore, it is optional and may be omitted to prevent the organic barrier layer 14 from being formed on the first inorganic barrier layer 12 formed on the top surface and the side surface of the protruding structure 22a by any of the following methods. The following methods are usable to prevent the entirety of the organic barrier layer 14 from being formed on the first inorganic barrier layer 12 formed on the top surface and the side surface of the protruding structure 22a, and is also usable to prevent a part of the organic barrier layer 14 from being formed (e.g., to prevent the organic barrier layer 14 having at least a certain thickness from being formed).

For example, after a photocured resin layer is formed by the method described in Patent Document No. 1 or 2, a step of partially removing the photocured resin layer by a dry process may be performed. The expression “remove an organic material by a dry process” indicates removing an organic material by ashing or by a dry process other than ashing (e.g., by sputtering). The organic material is removed from the surface. The expression “remove an organic material by a dry process” encompasses removing the organic material entirely and removing the organic material partially (e.g., from the surface to a level of a certain depth). The “dry process” refers to a process that is not a wet process using a liquid such as a release liquid, a solvent or the like. Ashing may be performed in, for example, an atmosphere containing at least one of N₂O, O₂ and O₃. Ashing is roughly classified into plasma ashing (or corona discharge) using plasma generated by treating any one of the above-described types of atmospheric gas at a high frequency, and photo-excited ashing of irradiating atmospheric gas with light such as ultraviolet rays or the like. Ashing may be performed by use of, for example, a known plasma ashing device, a known ashing device using corona discharge, a known photo-excited ashing device, a known UV ozone ashing device or the like. In the case where an SiN film is formed by CVD as each of the first inorganic barrier layer 12 and the second inorganic barrier layer 16, N₂O is used as material gas. Therefore, use of N₂O for ashing provides an advantage of simplifying the ashing device.

Alternatively, selective exposure such as mask exposure or the like may be performed at the time of curing a photocurable resin. An opening of the organic barrier layer 14 is formed in a region corresponding to a light-blocking portion of the photomask. Therefore, for example, the photocurable resin may be exposed to light via a photomask including a light-blocking portion in a region overlapping the protruding structure 22a as seen in the direction normal to the substrate. In this manner, the organic barrier layer 14 having an opening in the region overlapping the protruding structure 22a is provided.

At the time of curing the photocurable resin, a predetermined region of the photocurable resin may be irradiated with a laser beam having a wavelength of 400 nm or shorter, so that the selective exposure is performed. A coherent laser beam emitted from, for example, a semiconductor laser device is used. Therefore, the light beam travels highly straight, and thus the selective exposure is realized with no need of putting the mask into close contact with the element substrate.

Alternatively, infrared rays may be selectively directed toward a specific region, so that the photocured resin layer is not formed in the specific region. The step of forming the organic barrier layer 14 may include step A of forming a liquid film of the photocurable resin on the substrate; step B of selectively directing, for example, infrared rays toward a first region overlapping the protruding structure 22a to vaporize the photocurable resin in the first region; and step C of, after the step B, directing light to which the photocurable resin is sensitive (e.g., ultraviolet rays) toward a second region, including the first region, on the substrate (e.g., toward the entire surface of the substrate), thus to cure the photocurable resin in the second region, and as a result, forming the photocured resin layer. It is preferred that visible light to be directed instead of, or together with, the infrared rays has a wavelength exceeding 550 nm. The protruding structure 22a may be formed of a material having a large heat capacity.

The surface (e.g., the top portion and the side surface) of the protruding structure 22a may be liquid-repelling against a photocurable resin. For example, a photolithography process and a silane coupling agent may be used to modify a specific region of the surface of the protruding structure 22a to be hydrophobic. Alternatively, the protruding structure 22a may be formed of a resin material that is liquid-repelling against a photocurable resin.

FIG. 6(a) is a cross-sectional view taken along line 6A-6A′ in FIG. 2, and shows a portion including a particle P. The particle P is a microscopic dust particle generated during the production of the OLED display device, and is, for example, a microscopic piece of broken glass, a metal particle or an organic particle. Such a particle P is generated especially easily in the case where mask vapor deposition is used.

As shown in FIG. 6(a), the organic barrier layer (solid portion) 14 includes a portion 14b formed around the particle P. A reason for this is that an acrylic monomer supplied after the first inorganic barrier layer 12 is formed is condensed and present locally, more specifically, around a surface of a first inorganic barrier layer 12a on the particle P (the surface has a tapering angle larger than 90 degrees). The organic barrier layer 14 includes the opening (non-solid portion) on the flat portion of the first inorganic barrier layer 12.

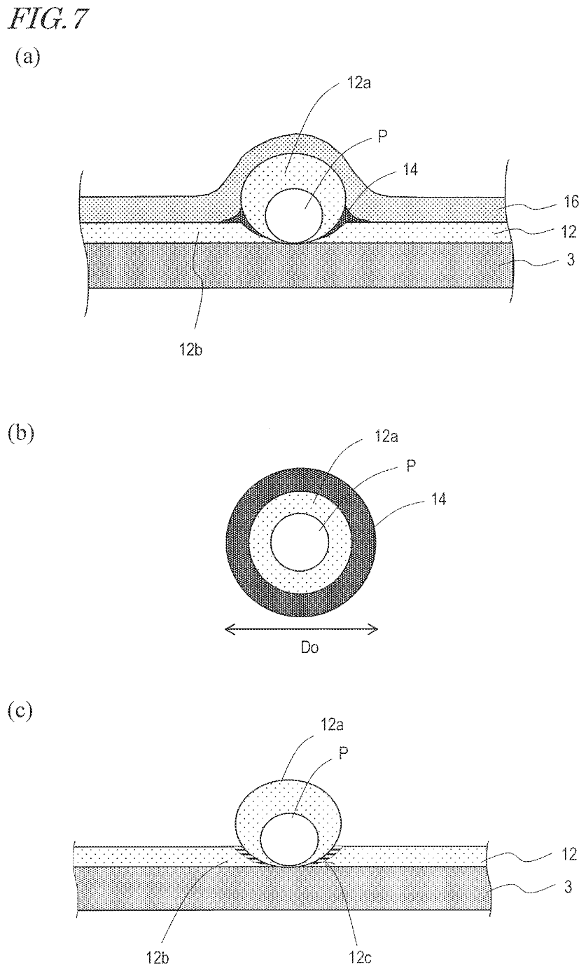

Now, with reference to FIG. 7(a) through FIG. 7(c), a structure of the portion including the particle P will be described. FIG. 7(a) is an enlarged view of the portion including the particle P shown in FIG. 6(a). FIG. 7(b) is a schematic plan view showing the size relationship among the particle P, the first inorganic barrier layer (SiN layer) 12 covering the particle P and the organic barrier layer 14. FIG. 7(c) is a schematic cross-sectional view of the first inorganic barrier layer 12 covering the particle P.

As shown in FIG. 7(c), in the case where the particle P (having a diameter, for example, longer than, or equal to, 1 μm) is present, a defect (crack) 12c may be formed in the first inorganic barrier layer 12. This is considered to be caused by impingement of the SiN layer 12a growing from a surface of the particle P and an SiN layer 12b growing from a flat portion of a surface of the OLED 3. The defect 12c is a portion having a low density (low film density), and in an extreme case, may become a crack 12c. In the case where such a defect 12c is present, the level of barrier property of the TFE structure 10A is decreased.

In the TFE structure 10A of the OLED display device 100A, as shown in FIG. 7(a), the organic barrier layer 14 is formed to fill the defect 12c of the first inorganic barrier layer 12, and a surface of the organic barrier layer 14 couples the surface of the first inorganic barrier layer 12a on the particle P and a surface of the first inorganic barrier layer 12b on the flat portion of the OLED 3 to each other continuously and smoothly. As described above, the organic barrier layer 14 is formed by curing a photocurable resin in a liquid state, and therefore, has a recessed surface formed by a surface tension. In this state, the photocurable resin exhibits a high level of wettability to the first inorganic barrier layer 12. If the level of wettability of the photocurable resin to the first inorganic barrier layer 12 is low, the surface of the organic barrier layer 14 may protrude, instead of being recessed. The organic barrier layer 14 may also be formed with a small thickness on the surface of the first inorganic barrier layer 12a on the particle P.

The organic barrier layer (solid portion) 14 having the recessed surface connects the surface of the first inorganic barrier layer 12a on the particle P and the surface of the first inorganic barrier layer 12b on the flat portion to each other continuously and smoothly. Therefore, the second inorganic barrier layer 16 formed thereon is a fine film with no defect. As can be seen, even if the particle P is present, the organic barrier layer 14 keeps high the level of barrier property of the TFE structure 10A.

As shown in FIG. 7(b), the organic barrier layer (solid portion) 14 is formed in a ring shape around the particle P. Where the particle P has a diameter (equivalent circle diameter) of, for example, about 1 μm as seen in the direction normal to the substrate, the ring-shaped solid portion has a diameter (equivalent circle diameter) D₀ that is, for example, longer than, or equal to, 2 μm.

In this example, the organic barrier layer 14 is formed only in a gap in the first inorganic barrier layer 12 formed on the particle P, and the particle P is already present before the first inorganic barrier layer 12 is formed on the OLED 3. Alternatively, the particle P may be present on the first inorganic barrier layer 12. In this case, the organic barrier layer 14 is formed only at the border, namely, in a gap, between the first inorganic barrier layer 12 and the particle P on the first inorganic barrier layer 12, and thus maintains the level of barrier property of the TFE structure 10A like in the above-described case. The organic barrier layer 14 may also be formed with a small thickness on the surface of the first inorganic barrier layer 12a on the particle P, or on the surface of the particle P. In this specification, the expression that “the organic barrier layer 14 is present around the particle P” encompasses all these forms.

The organic barrier layer (solid portion) 14 is not limited to being formed as in the example shown in FIG. 6(a), and may be formed only around the protruding portion at the surface of the first inorganic barrier layer 12 for substantially the same reason as that described above. Examples of other regions where the organic barrier layer (solid portion) 14 may be formed will be described below.

Now, with reference to FIG. 6(b), a structure of the TFE structure 10A on the lead wires 30 will be described. FIG. 6(b) is a cross-sectional view taken along line 6B-6B′ in FIG. 2, more specifically, is a cross-sectional view of portions 32 of the lead wires 30, the portions 32 being closer to the active region R1.

As shown in FIG. 6(b), the organic barrier layer (solid portion) 14 includes a portion 14c formed around each of the protruding portions at the surface of the first inorganic barrier layer 12, the protruding portions reflecting the cross-sectional shape of the portions 32 of the lead wires 30.

The lead wires 30 are patterned by the same step as that of, for example, the gate bus lines or the source bus lines. Therefore, in this example, the gate bus lines and the source bus lines formed in the active region R1 also have the same cross-sectional structure as that of the portions 32 shown in FIG. 6(b), of the lead wires 30, closer to the active region R1. It should be noted that typically, a flattening layer is formed on the gate bus lines and the source bus lines formed in the active region R1, and thus no stepped portion is formed at the surface of the first inorganic barrier layer 12 on the gate bus lines and the source bus lines.

The portions 32 of the lead wires 30 may have, for example, a forward tapering side surface portion (inclining side surface portion) having a tapering angle smaller than 90 degrees. In the case where the lead wires 30 include the forward tapering side surface portion, formation of defects in the first inorganic barrier layer 12 and the second inorganic barrier layer 16 formed on the lead wires 30 is prevented. Namely, the moisture-resistance reliability of the TFE structure 10A is improved. The tapering angle of the forward tapering side surface portion is preferably smaller than, or equal to, 70 degrees.

The active region R1 of the OLED display device 100, except for the regions where the organic barrier layer 14 is selectively formed, is substantially covered with the inorganic barrier layer joint portion, in which the first inorganic barrier layer 12 and the second inorganic barrier layer 16 are in direct contact with each other. Therefore, it does not occur that the organic barrier layer 14 acts as a moisture entrance route to allow the moisture to reach the active region R1 of the OLED display device.

The OLED display device 100 according to an embodiment of the present invention is preferably usable for, for example, medium- to small-sized high-definition smartphones and tablet terminals. In a medium- to small-sized (e.g., 5.7-inch) high-definition (e.g., 500 ppi) OLED display device, it is preferred that the lines (encompassing the gate bus lines and the source bus lines) in the active region R1 have a cross-sectional shape, in a direction parallel to a line width direction thereof, close to a rectangle (side surfaces of the lines have a tapering angle of about 90 degrees) in order to have a sufficiently low resistance with a limited line width. Therefore, in order to form the lines having a low resistance, the tapering angle of the forward tapering side surface portion TSF may be larger than 70 degrees and smaller than 90 degrees, or the tapering angle of the lines may be about 90 degrees in the entire length of the lines with no forward tapering side surface portion TSF being provided.

Now, FIG. 6(c) will be referred to. FIG. 6(c) is a cross-sectional view of a region where the TFE structure 10A is not formed. In this region, the terminals 38 have the same cross-sectional structure as that of portions 36 of the lead wires 30 shown in FIG. 6(c). The portions 36 of the lead wires 30 shown in FIG. 6(c) may have a tapering angle of, for example, about 90 degrees.

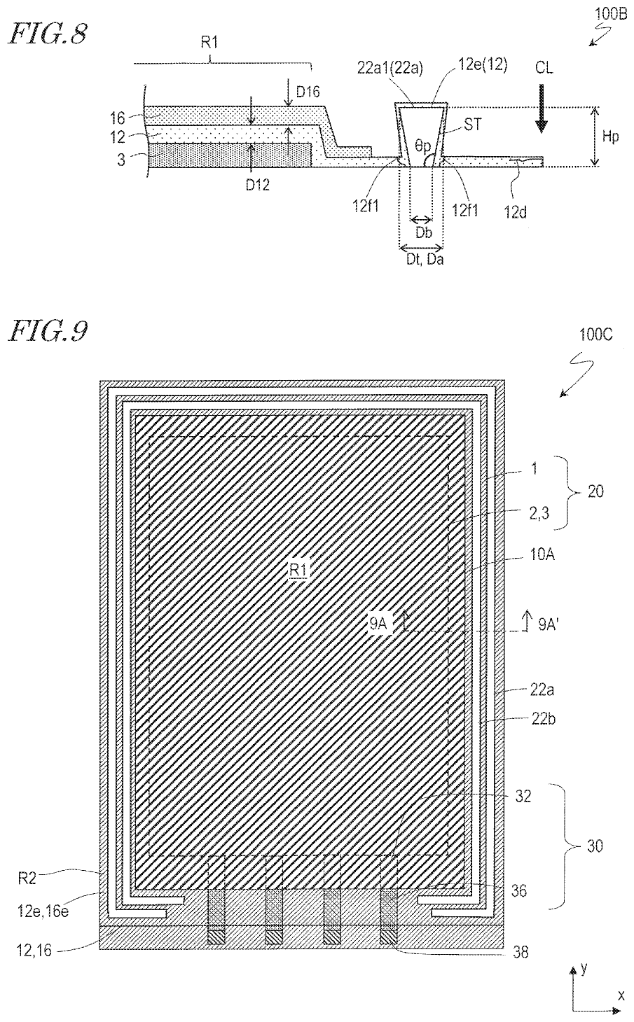

With reference to FIG. 8, a structure of another OLED display device 100B according to embodiment 1 of the present invention will be described. FIG. 8 is a schematic cross-sectional view of the OLED display device 100B.

As shown in FIG. 8, unlike in the OLED display device 100A, in the OLED display device 100B, the second inorganic barrier layer 16 is formed so as not to overlap the protruding structure 22a as seen in the direction normal to the substrate. An outer perimeter of the second inorganic barrier layer 16 is inner to the protruding structure 22a.

The OLED display device 100B having such a structure also provides substantially the same effects as those of the OLED display device 100A.

As described above, as long as the active region R1 is enclosed by the inorganic barrier layer joint portion, the first inorganic barrier layer 12 and the second inorganic barrier layer 16 may have any shape.

FIG. 8 shows the OLED display device 100B including the protruding structure 22a1 having the inverted tapering side surface. The OLED display device is not limited to including such a protruding structure, and may include any of the protruding structures described above.

Hereinafter, modifications of the protruding structure will be described. OLED display devices 100C through 100E described below as examples each have a feature in the planar shape (shape as seen in the direction normal to the substrate) of the protruding structure. The OLED display devices 100C through 100E are applicable to any of the above-described OLED display devices. The protruding structure included in each of the OLED display devices 100C through 100E may have a cross-sectional shape (shape of the cross-section perpendicular to the direction in which the protruding structure extends) of any of the protruding structures described above.

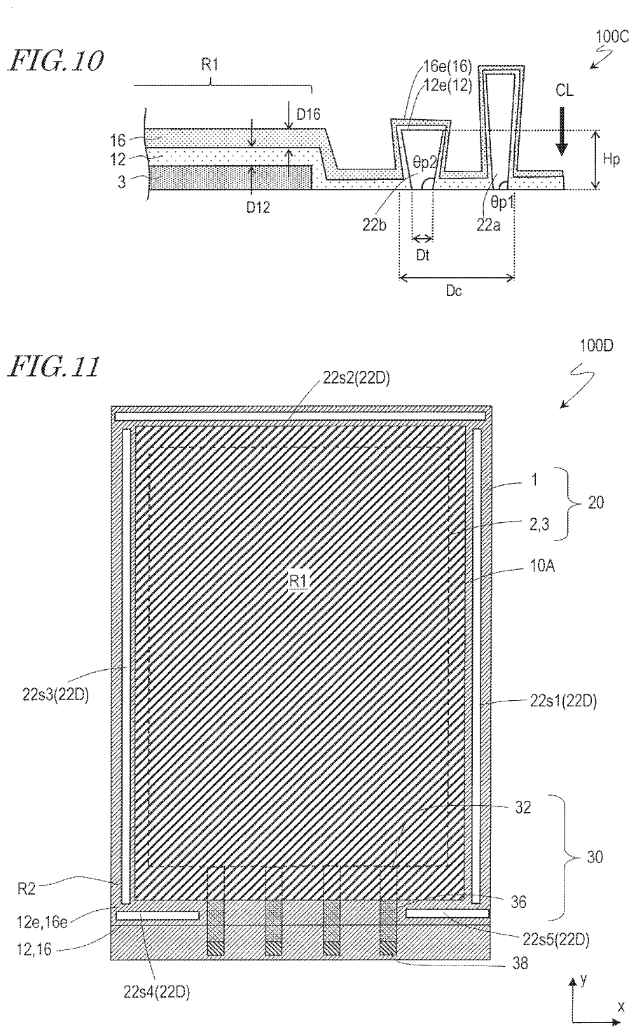

With reference to FIG. 9 and FIG. 10, still another OLED display device 100C according to embodiment 1 of the present invention will be described. FIG. 9 is a schematic plan view of the OLED display device 100C, and FIG. 10 is a schematic cross-sectional view of the OLED display device 100C. FIG. 10 does not show the cracks or defects generated in the inorganic barrier layers, for the sake of simplicity.

As shown in FIG. 9 and FIG. 10, unlike the OLED display device 100A, the OLED display device 100C further includes a protruding structure 22b (may also be referred to as a “second protruding structure 22b”) between the protruding structure 22a (may also be referred to as a “first protruding structure 22a”) and the active region R1. The protruding structure 22b includes a portion extending along at least one side of the active region R1.

The OLED display device 100C includes the first protruding structure 22a and the second protruding structure 22b, and thus prevents a crack from reaching the active region R1 more effectively than the OLED display device 100A.

The first protruding structure 22a and the second protruding structure 22b each include a portion extending along three sides, among the four sides of the active region R1, other than the side along which the plurality of terminals are provided. In this example, the first protruding structure 22a and the second protruding structure 22b include portions extending generally parallel to each other.

Depth Dc of a region where the first protruding structure 22a and the second protruding structure 22b are provided is, for example, about several hundred micrometers. Therefore, the provision of the first protruding structure 22a and the second protruding structure 22b does not significantly influence the reduction in the width of the frame portion of the OLED display device.

It is preferred that the first protruding structure 22a and the second protruding structure 22b each have a cross-sectional shape that satisfies the above-described conditions. The cross-sectional shape of the first protruding structure 22a and the cross-sectional shape of the second protruding structure 22b may be the same as, or different from, each other. For example, tapering angle θp1 of the first protruding structure 22a and tapering angle θp2 of the second protruding structure 22b may be equal to, or different from, each other.

As shown in FIG. 10, the first protruding structure 22a, which is farther from the active region R1, may have a height greater than a height of the second protruding structure 22b, which is closer to the active region R1. In this case, the first protruding structure 22a may also act as a spacer as described above.

The OLED display device in this embodiment may include three or more protruding structures, needless to say.

With reference to FIG. 11, a structure of still another OLED display device 100D according to embodiment 1 of the present invention will be described. FIG. 11 is a schematic plan view of the OLED display device 100D.

As shown in FIG. 11, a protruding structure 22D included in the OLED display device 100D includes a plurality of sub structures 22s1, 22s2, 22s3, 22s4 and 22s5. The plurality of sub structures 22s1 through 22s5 may collectively be referred to as the “protruding structure 22D”. The protruding structure 22D includes the sub structures 22s1 and 22s3 respectively extending along sides of the active region R1 that extend in a y-axis direction, the sub structure 22s2 extending along a side along which the plurality of terminals 38 or the plurality of lead wires 30 are not provided, among the sides of the active region R1 that extend in the x-axis direction, and the sub structures 22s4 and 22s5 extending along a side along which the plurality of terminals 38 and the plurality of lead wires 30 are provided, among the sides of the active region R1 that extend in the x-axis direction.

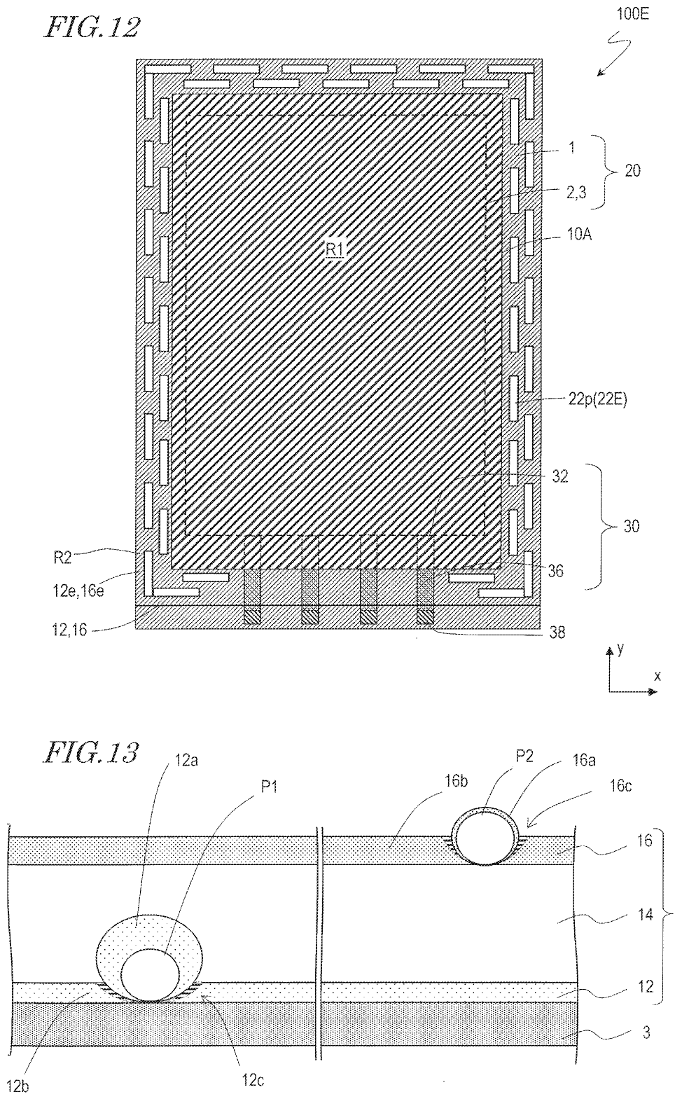

With reference to FIG. 12, a structure of still another OLED display device 100E according to embodiment 1 of the present invention will be described. FIG. 12 is a schematic plan view of the OLED display device 100E.

As shown in FIG. 12, a protruding structure 22E included in the OLED display device 100E includes a plurality of sub structures 22p. The plurality of sub structures 22p may collectively be referred to as the “protruding structure 22E”. The plurality of sub structures 22p are located in a region except for the region where the plurality of terminals 38 are provided, and are located so as to interrupt a line connecting the cutting line CL and the outer perimeter of the active region R1 to each other.

The plurality of sub structures 22p may each have any planar shape as seen in the direction normal to the substrate. Two or more sub structures 22p may be connected with each other. Top surfaces of the sub structures 22p may have substantially the same size as, or different sizes from, each other. In the case where the sub structures have the same planar shape and the same size as each other, there is an advantage that, for example, a photomask used to form the protruding structure 22E by a photolithography process may be simplified.

### Embodiment 2

An OLED display device according to this embodiment is different from the OLED display device according to the above-described embodiment in the structure of the thin film encapsulation structure. The OLED display device according to this embodiment has a feature in the thin film encapsulation structure. The thin film encapsulation structure in this embodiment is applicable to any of the above-described OLED display devices.

FIG. 13 is a cross-sectional view schematically showing a TFE structure 10B included in the OLED display device according to embodiment 2 of the present invention. In the above-described embodiment, the organic barrier layer 14 included in the TFE structure 10A includes a plurality of solid portions distributed discretely. As shown in FIG. 13, the TFE structure 10B included in the OLED display device according to this embodiment includes a relatively thick organic barrier layer 14 (e.g., an organic barrier layer having a thickness exceeding about 5 μm and about 20 μm or less). The relatively thick organic barrier layer 14 also acts as a flattening layer having a thickness of, for example, 5 μm or greater. The relatively thick organic barrier layer 14 is formed so as to cover, for example, the active region of each of the OLED display device portions formed on the element substrate.

In FIG. 13, P1 represents a particle already present before the first inorganic barrier layer 12 or the second inorganic barrier layer 16 is formed, and P2 represents a particle formed during the formation of the first inorganic barrier layer 12 or the second inorganic barrier layer 16.

When the first inorganic barrier layer 12 is formed on the particle P1 already present before the first inorganic barrier layer 12 is formed, the portion 12a growing from a surface of the particle P1 and the portion 12b growing from the flat portion of the OLED 3 impinge on each other, and as a result, the defect 12c is formed. Similarly, when the particle P2 is generated during the formation of the second inorganic barrier layer 16, a defect (e.g., crack) 16c is formed in the second inorganic barrier layer 16. The particle P2 is generated during the formation of the second inorganic barrier layer 16. Therefore, a portion 16a, of the second inorganic barrier layer 16, that is formed on the particle P2 is shown as being thinner than a portion 16b formed on the flat portion.

Such a relatively thick organic barrier layer 14 may be formed by, for example, inkjet printing. In the case where a printing method such as inkjet printing or the like is used to form an organic barrier layer, the organic barrier layer may be adjusted to be formed only in the active region on the element substrate but not to be formed in a region overlapping the protruding structure.

### INDUSTRIAL APPLICABILITY

Embodiments of the present invention are applicable to an organic EL display device, especially, a flexible organic EL display device, and a method for producing the same.

### REFERENCE SIGNS LIST

1 substrate (flexible substrate)
2 back plane (circuit)
3 organic EL element
4 polarizing plate
10, 10A, 10B thin film encapsulation structure (TFE structure)
12 first inorganic barrier layer
14 organic barrier layer
16 second inorganic barrier layer
22a, 22a1, 22a2, 22b, 22D, 22E protruding structure
30 lead wire
38 terminal
100, 100A, 100A1, 100A2 organic EL display device
100B, 100C, 100D, 100E organic EL display device
200A mother panel

1-20. (canceled)

21. An organic electroluminescent device including an active region that includes a plurality of organic electroluminescent elements and also including a peripheral region located in a region other than the active region, the organic electroluminescent device comprising:
an element substrate including a substrate and the plurality of organic electroluminescent elements supported by the substrate; and
a thin film encapsulation structure covering the plurality of organic electroluminescent elements,
wherein the thin film encapsulation structure includes a first inorganic barrier layer, an organic barrier layer in contact with a top surface of the first inorganic barrier layer, and a second inorganic barrier layer in contact with the top surface of the first inorganic barrier layer and a top surface of the organic barrier layer,
wherein the peripheral region includes a first protruding structure supported by the substrate, the first protruding structure including a portion extending along at least one side of the active region, and also includes an extending portion, of the first inorganic barrier layer, extending onto the first protruding structure,
wherein the first protruding structure includes a first portion and a second portion, the first portion is closer to a top portion of the first protruding structure than the second portion, and as seen in a direction normal to the substrate, a first cross-section, parallel to a surface of the substrate, of the first portion includes a portion that does not overlap a second cross-section, parallel to the surface of the substrate, of the second portion,
wherein as seen in a cross-section perpendicular to a direction in which the first protruding structure extends, the first protruding structure includes a protruding portion protruding in a direction generally perpendicular to a height direction of the first protruding structure, and the protruding portion includes the first portion,
wherein the first protruding structure includes a lower layer and an upper layer formed on the lower layer, the upper layer includes the first portion, the lower layer includes the second portion, and in a cross-section perpendicular to a direction in which the first protruding structure extends, a width of a bottom portion of the upper layer is greater than a width of a top portion of the lower layer, and
wherein the lower layer contains a photosensitive resin, and the upper layer contains silicon nitride.

22. The organic electroluminescent device of claim 21, wherein the lower layer contains an acrylic resin.

23. The organic electroluminescent device of claim 21, wherein the first protruding structure has a height greater than a thickness of the first inorganic barrier layer.

24. The organic electroluminescent device of claim 21, wherein the first protruding structure has a height that is at least three times as great as a thickness of the first inorganic barrier layer.

25. The organic electroluminescent device of claim 21, wherein as seen in a cross-section perpendicular to a direction in which the first protruding structure extends, the first protruding structure includes an inverted tapering portion in which a side surface of the first protruding structure has a tapering angle exceeding 90 degrees, and the inverted tapering portion includes the first portion and the second portion.

26. The organic electroluminescent device of claim 21, wherein the peripheral region includes an extending portion, of the second inorganic barrier layer, formed on the extending portion of the first inorganic barrier layer.

27. The organic electroluminescent device of claim 26, wherein the first protruding structure has a height that is at least three times as great as a sum of a thickness of the first inorganic barrier layer and a thickness of the second inorganic barrier layer.

28. The organic electroluminescent device of claim 21, wherein as seen in a direction normal to the substrate, the second inorganic barrier layer does not overlap the first protruding structure.

29. The organic electroluminescent device of claim 21, wherein the element substrate further includes a bank layer defining each of a plurality of pixels each including any of the plurality of organic electroluminescent elements, and the first protruding structure has a height greater than, or equal to, a thickness of the bank layer.

30. The organic electroluminescent device of claim 21, wherein the first protruding structure includes a portion extending along three sides of the active region.

31. The organic electroluminescent device of claim 21,
wherein the element substrate includes a plurality of gate bus lines each connected with any of the plurality of organic electroluminescent elements, and a plurality of source bus lines each connected with any of the plurality of organic electroluminescent elements,
wherein the peripheral region includes a plurality of terminals provided in a region in the vicinity of a certain side of the active region, and a plurality of lead wires connecting each of the plurality of terminals and either one of the plurality of gate bus lines or either one of the plurality of source bus lines to each other, and
wherein the first protruding structure includes a portion extending along three sides of the active region other than the certain side.

32. The organic electroluminescent device of claim 21,
wherein the organic barrier layer includes a plurality of solid portions distributed discretely, and
wherein the second inorganic barrier layer is in contact with the top surface of the first inorganic barrier layer and top surfaces of the plurality of solid portions of the organic barrier layer.

33. The organic electroluminescent device of claim 21, wherein the organic barrier layer acts as a flattening layer having a thickness of 5 μm or greater.

34. The organic electroluminescent device of claim 21, wherein the peripheral region includes a second protruding structure between the active region and the first protruding structure, the second protruding structure extending along at least one side of the active region.

35. The organic electroluminescent device of claim 21, wherein the first protruding structure includes a plurality of sub structures.

36. A method for producing the organic electroluminescent device of claim 21, comprising the steps of:
preparing a mother element substrate including a mother substrate and a plurality of active regions supported by the mother substrate, the plurality of active regions each including the plurality of organic electroluminescent elements;
forming the thin film encapsulation structure in each of the plurality of active regions, the thin film encapsulation structure covering the plurality of organic electroluminescent elements; and
dividing, after the step of forming the thin film encapsulation structure, the plurality of active regions into individual active regions,
wherein the step of preparing the mother element substrate includes step a1 of forming the first protruding structure in each of the plurality of active regions, the first protruding structure including a portion extending along at least one side of the corresponding active region,
wherein the step of forming the thin film encapsulation structure includes:
step A of forming the first inorganic barrier layer on the first protruding structure such that the first inorganic barrier layer covers the first protruding structure,
step B of, after the step A, forming the organic barrier layer on the first inorganic barrier layer, and
step C of, after the step B, forming the second inorganic barrier layer on the first inorganic barrier layer and the organic barrier layer,
wherein the step of dividing the plurality of active regions includes the step of cutting the mother substrate and the first inorganic barrier layer such that individual cut portions each include either one of the plurality of active regions and the first protruding structure formed in the corresponding active region,
wherein the step a1 includes:
step a11 of forming a lower film on the mother substrate,
step a12 of forming an upper film on the lower film,
step a13 of patterning the upper film to form the upper layer, and
step a14 of patterning the lower film to form the lower layer, and
wherein the lower film contains a photosensitive resin, and the upper film contains silicon nitride.

37. The method of claim 36,
wherein the step of preparing the mother element substrate further includes step a2 of forming a bank layer defining each of a plurality of pixels each including either one of the plurality of organic electroluminescent elements, and
wherein the step a1 and the step a2 include the step of patterning the same resin film.

38. The method of claim 36, wherein the lower film contains an acrylic resin.

39. The method of claim 36, wherein the step a13 includes the step of etching the upper film by use of hydrofluoric acid.
